(19) United States
(12) Patent Application Publication
(10) Pub. No.: US 2026/0156907 A1
(43) Pub. Date: Jun. 4, 2026

(54) DIFFUSION CONTROL IN SOURCE/DRAIN FEATURES

(71) Applicant: Taiwan Semiconductor Manufacturing Company, Ltd., Hsinchu (TW)

(72) Inventors: Shih-Hao Lin, Hsinchu (TW); Yen-Po Lin, Taipei City (TW); Wei Hao Lu, Taoyuan City (TW); Chih-Hsiang Huang, Hsinchu County (TW); Ping-Wei Wang, Hsin-Chu (TW)

(21) Appl. No.: 19/183,415

(22) Filed: Apr. 18, 2025

Related U.S. Application Data
(60) Provisional application No. 63/727,769, filed on Dec. 4, 2024.

(51) Int. Cl. H10D 84/01; H01L 21/02; H10D 30/00; H10D 30/01; H10D 30/43; H10D 62/10; H10D 62/13; H10D 62/834; H10D 64/01; H10D 84/83

(52) U.S. Cl. CPC H10D 84/013; H10D 30/014; H10D 30/0191; H10D 62/102; H10D 62/834; H10D 64/017; H10P 14/3411; H10D 30/43; H10D 30/502; H10D 62/121; H10D 62/151; H10D 84/832

(57) ABSTRACT

A method according to the present disclosure includes forming, over a substrate, a semiconductor stack that includes first semiconductor layers interleaved by second semiconductor layers, patterning the semiconductor stack and the substrate to form a fin-shaped structure, forming a dummy gate stack over the fin-shaped structure, recessing the fin-shaped structure to form a source/drain recess, selectively recessing the plurality of second semiconductor layers to form inner spacer recesses, forming inner spacer features in the inner spacer recesses, depositing a first epitaxial layer over the source/drain recess, depositing a second epitaxial layer over the first epitaxial layer, depositing a buffer layer over the second epitaxial layer, depositing a third epitaxial layer over the buffer layer, removing the dummy gate stack, selectively removing the second semiconductor layers to release the first semiconductor layers as channel members, and forming a gate structure to wrap around each of the channel members.

### PRIORITY DATA

This application claims priority to U.S. Provisional Patent Application No. 63/727,769 filed Dec. 4, 2024, the entirety of which is hereby incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-14 illustrate fragmentary cross-sectional views of a precursor structure during a fabrication process according to the method of FIG. 1, according to one or more aspects of the present disclosure.

FIG. 15 illustrates a flowchart of a method for forming a source/drain feature of a multi-gate transistor, according to one or more aspects of the present disclosure.

FIGS. 16-21 illustrate fragmentary cross-sectional views of a precursor structure during a fabrication process according to the method of FIG. 15, according to one or more aspects of the present disclosure.

FIG. 22 illustrates a flowchart of a method for forming a source/drain feature of a multi-gate transistor, according to one or more aspects of the present disclosure.

FIGS. 23-29 illustrate fragmentary cross-sectional views of a precursor structure during a fabrication process according to the method of FIG. 22, according to one or more aspects of the present disclosure.

FIG. 30 illustrates a flowchart of a method for forming a source/drain feature of a multi-gate transistor, according to one or more aspects of the present disclosure.

FIGS. 31-36 illustrate fragmentary cross-sectional views of a precursor structure during a fabrication process according to the method of FIG. 30, according to one or more aspects of the present disclosure.

FIG. 37 illustrates how features formed according to methods in FIG. 15, 22 or 30 affect an n-type dopant concentration distribution in a source/drain feature.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to multi-gate transistors and fabrication methods, and more particularly to source/drain features of GAA transistors. Channel regions of a GAA transistor may be disposed in nanowire channel members, bar-shaped channel members, nanosheet channel members, nanostructure channel members, column-shaped channel members, post-shaped channel members, and/or other suitable channel configurations. Depending on the shapes of the channel members, GAA transistors may also be referred to as nanowire transistors or nanosheet transistors. Despite of the shapes, each of the channel members of a GAA transistor extend between and interface two source/drain features. In some existing technologies, the source/drain features includes multiple epitaxial layers and some of the multiple epitaxial layers include a relatively high dopant concentration by design. There are concerns that the dopant in these epitaxial layers may diffuse to other epitaxial layers, causing variation in threshold voltages and increased contact resistance. The presence of voids reduces volume of doped source/drain materials, resulting in increased resistance.

The present disclosure provides methods for forming source/drain features that include one or more buffer layers to control out-diffusion of dopants. Particularly, the present disclosure provides methods of forming an n-type source/drain feature. The n-type source/drain features formed using methods of the present disclosure includes a first epitaxial layer interfacing a channel member, a second epitaxial layer over the first epitaxial layer, a buffer layer over the second epitaxial layer, and highly doped third epitaxial layer over the buffer layer. The buffer layer may include a silicon layer, an arsine-treated layer, or an arsenic-doped silicon layer. The buffer layer functions to prevent n-type dopant from diffusing from the third epitaxial layer into the second epitaxial layer. The prevention of out-diffusion of n-type dopant provides a stable threshold voltage and reduces contact resistance of the source/drain feature.

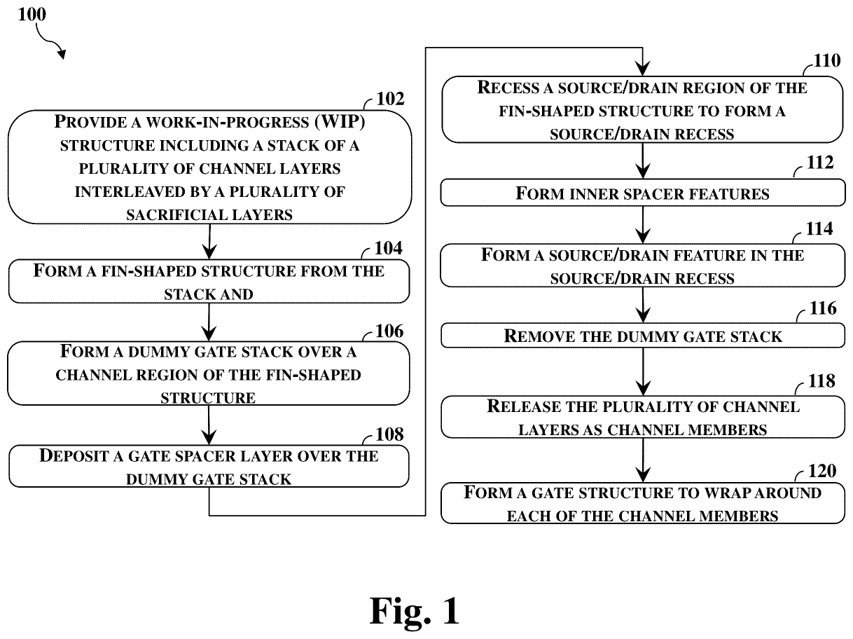

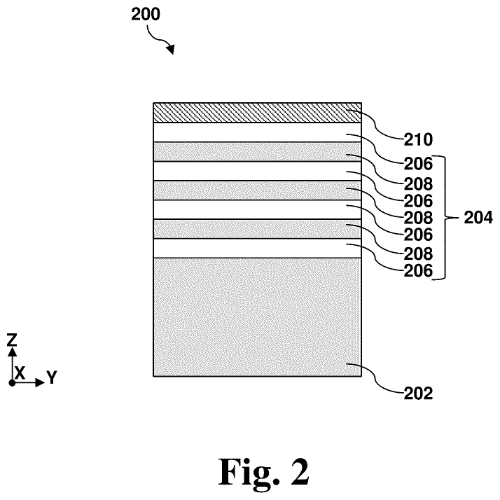

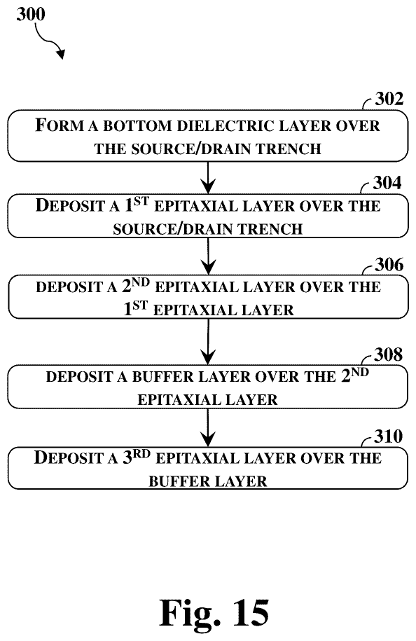

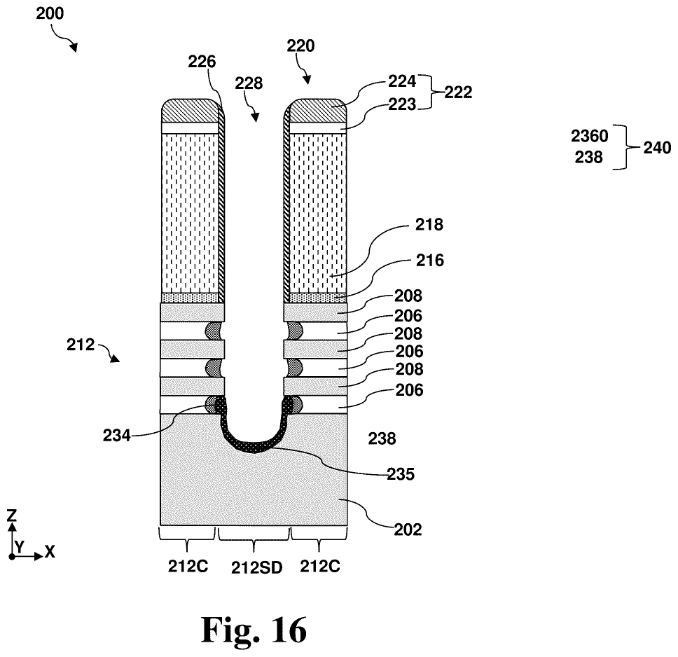

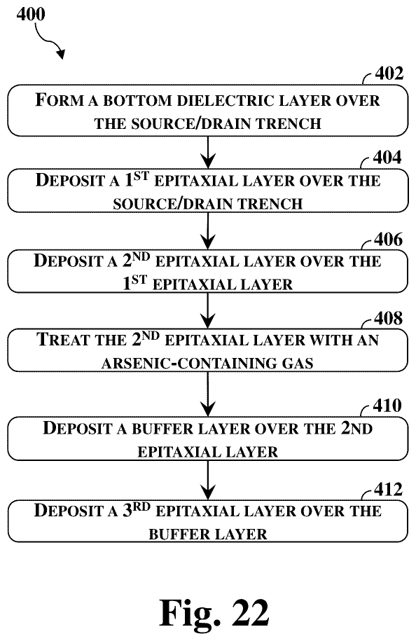

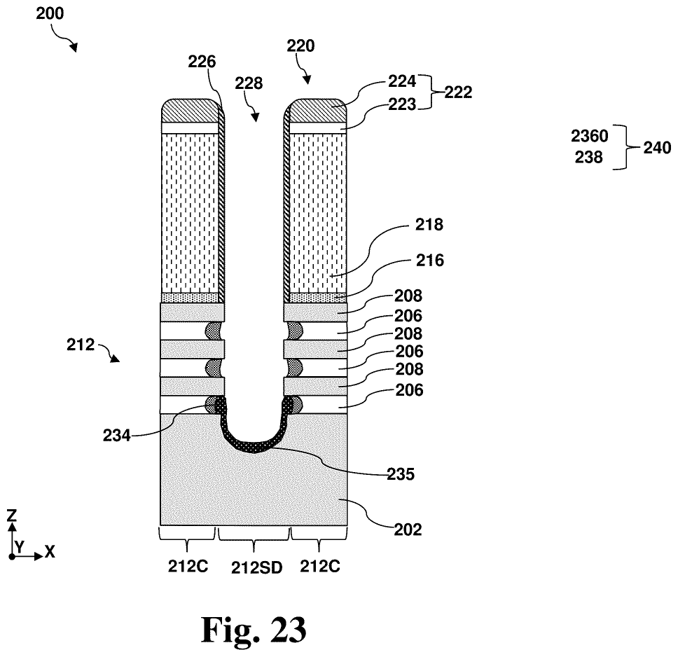

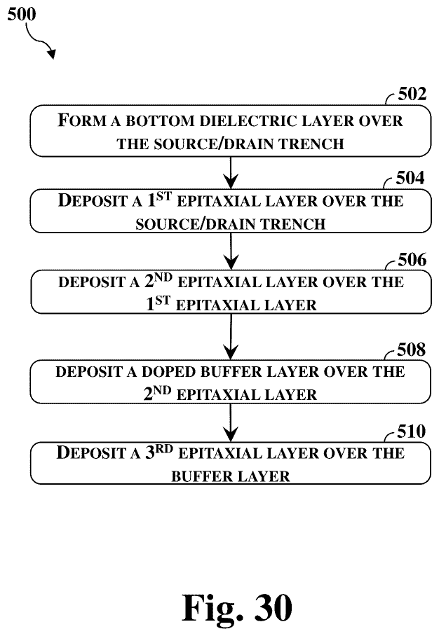

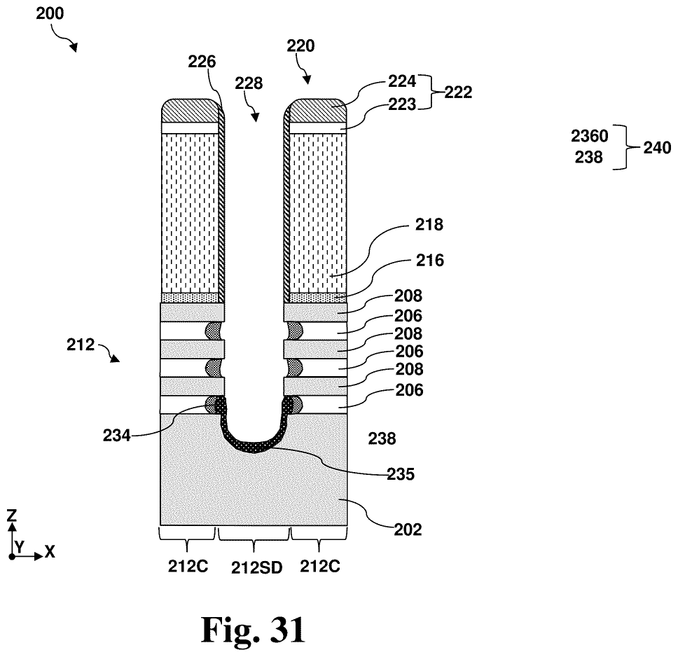

The various aspects of the present disclosure will now be described in more detail with reference to the figures. In that regard, FIG. 1 is a flowchart illustrating method 100 of forming a semiconductor structure from a precursor structure according to embodiments of the present disclosure. The semiconductor structure includes a source/drain feature and FIGS. 15, 22, and 30 are flowcharts illustrating methods 300, 400, and 500 of forming the source/drain feature of the semiconductor structure. Methods 100, 300, 400, and 500 are merely examples and are not intended to limit the present disclosure to what is explicitly illustrated in method 100, 300, 400, and 500. Additional steps can be provided before, during and after method 100, 300, 400, or 500, and some steps described can be replaced, eliminated, or moved around for additional embodiments of the method. Not all steps are described herein in detail for reasons of simplicity. Method 100 is described below in conjunction with FIG. 2-14, which are fragmentary cross-sectional views of a precursor structure at different stages of fabrication according to embodiments of the method 100 in FIG. 1. Method 300 is described below in conjunction with FIGS. 16-21, which are fragmentary cross-sectional views of a precursor structure at different stages of fabrication according to embodiments of the method 300 in FIG. 15. Method 400 is described below in conjunction with FIGS. 23-29, which are fragmentary cross-sectional views of a precursor structure at different stages of fabrication according to embodiments of the method 400 in FIG. 22. Method 500 is described below in conjunction with FIGS. 31-36, which are fragmentary cross-sectional views of a precursor structure at different stages of fabrication according to embodiments of the method 500 in FIG. 30. Because the precursor structure 200 will be fabricated into a semiconductor structure or a semiconductor device, the precursor structure 200 may be referred to herein as a semiconductor structure or a semiconductor device 200 as the context requires. For avoidance of ambiguity, the X, Y and Z directions in FIGS. 2-14, 16-21, 23-29, and 31-36 are perpendicular to one another. Throughout the present disclosure, unless expressly otherwise described, like reference numerals denote like features or steps. That is, material properties and comparisons thereof for various numbered elements described in association with a method or a figure should apply to the same numbered elements described in association with a different method or a different figure.

Referring to FIGS. 1 and 2, method 100 includes a block 102 where a stack 204 of alternating semiconductor layers is formed over the precursor structure 200. As shown in FIG. 2, the precursor structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that four (4) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10. In the embodiments represented in FIG. 2, the stack 204 includes a bottommost sacrificial layer 206 and a topmost sacrificial layer 206. In the embodiments, the topmost sacrificial layer 206 functions to protect the topmost channel layer and may be completely consumed in subsequent processes.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

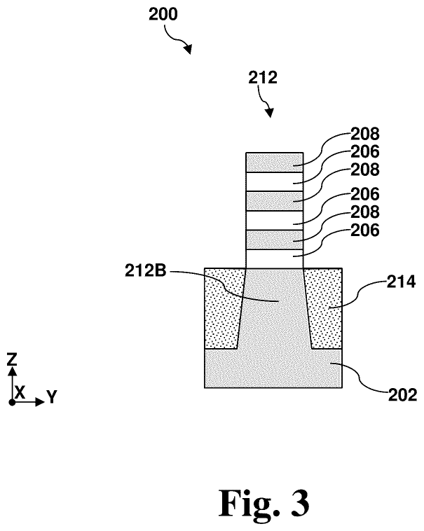

Referring to FIGS. 1, 2 and 3, method 100 includes a block 104 where a fin-shaped structure 212 is formed from the stack 204 and the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the isolation feature 214 shown in FIG. 3. The fin-shaped structure 212 rises above the STI feature 214 after the recessing, while the base fin structure 212B is embedded or buried in the isolation feature 214. Because the material of the isolation feature 214 contains silicon and oxygen atoms, it can be said that the isolation feature 214 includes an oxide-based material.

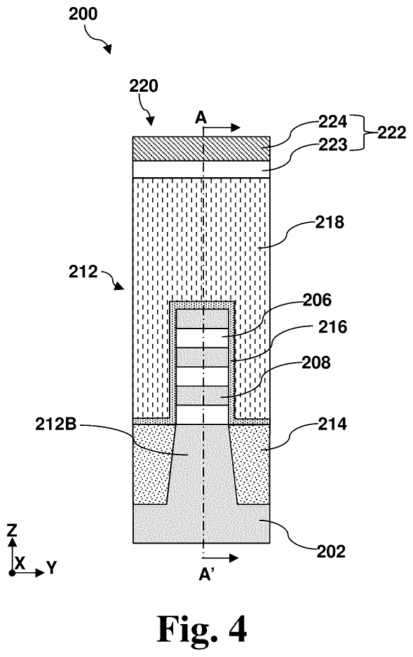

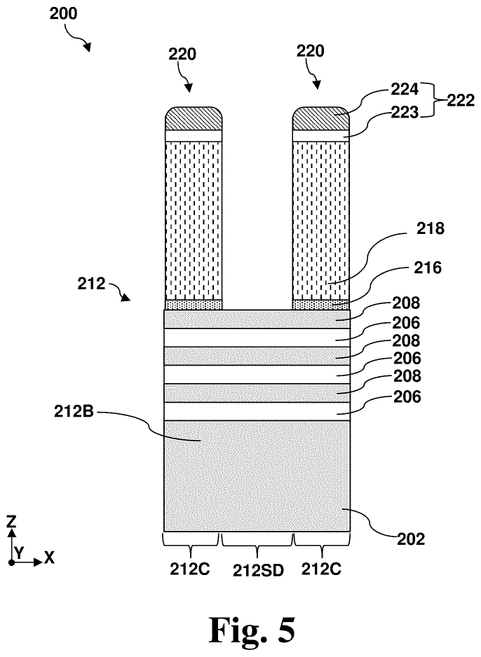

Referring to FIGS. 1, 4 and 5, method 100 includes a block 106 where a dummy gate stack 220 is formed over a channel region 212C of the fin-shaped structure 212. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the source region 212SD is disposed between two channel regions 212C along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be deposited over the precursor structure 200. In some embodiments, the dummy dielectric layer 216 may be formed on the fin-shaped structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon (poly-Si). For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

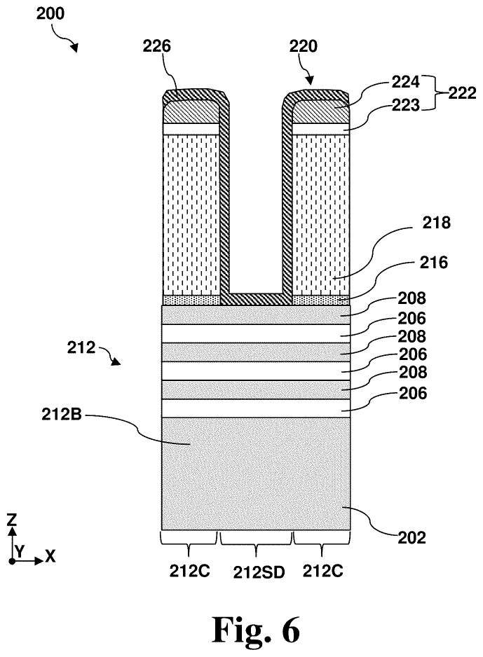

Referring to FIGS. 1 and 6, method 100 includes a block 108 where a gate spacer layer 226 is deposited over the precursor structure 200, including over the dummy gate stack 220. In some embodiments, the gate spacer layer 226 is deposited conformally over the precursor structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

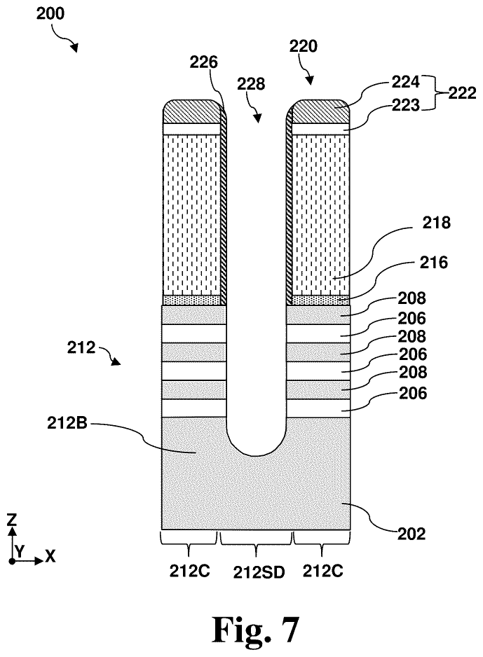

Referring to FIGS. 1 and 7, method 100 includes a block 110 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

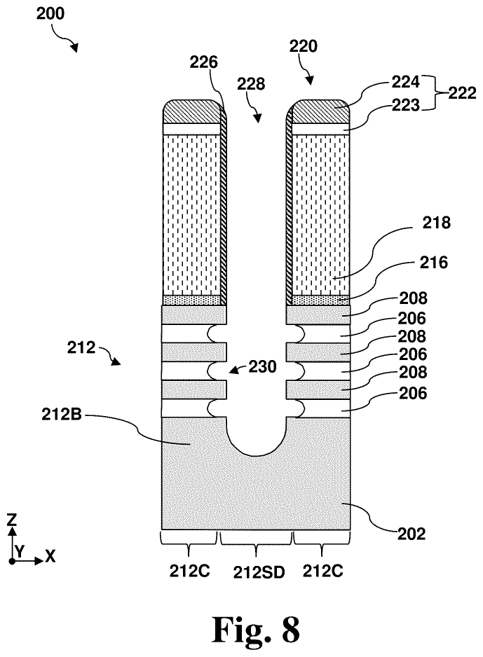

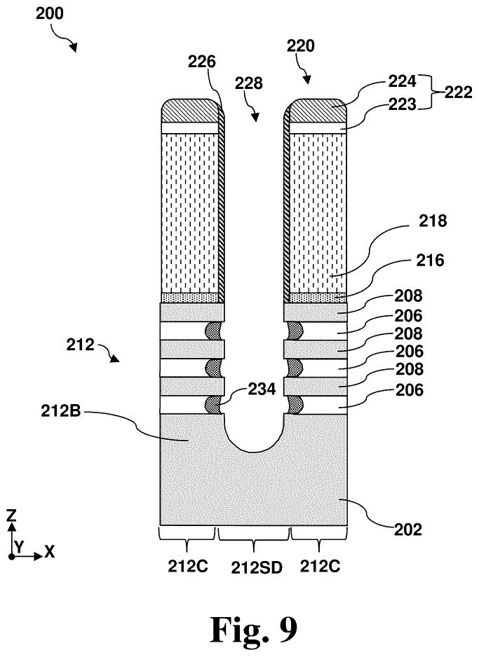

Referring to FIGS. 1, 8 and 9, method 100 includes a block 112 where inner spacer features 234 are formed. While not shown explicitly, operation at block 112 may include selective and partial removal of the sacrificial layers 206 to form inner spacer recesses 230 (shown in FIG. 8), deposition of inner spacer material over the precursor structure 200, and etch back the inner spacer material to form inner spacer features 234 in the inner spacer recesses 230 (shown in FIG. 9). Referring to FIG. 8, the sacrificial layers 206 exposed in the source/drain trenches 228 are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the inner spacer recesses 230 are formed, an inner spacer material is deposited over the precursor structure 200, including over the inner spacer recesses 230. The inner spacer material may include silicon oxide, silicon oxycarbonitride, silicon nitride, silicon oxynitride, carbon-rich silicon carbonitride, or a low-k dielectric material. In one embodiment, the inner spacer features 234 include silicon oxycarbonitride. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. Referring to FIG. 9, the deposited inner spacer material is then etched back to remove the inner spacer material from the sidewalls of the channel layers 208 to form the inner spacer features 234 in the inner spacer recesses 230. At block 112, the inner spacer material may also be removed from the top surfaces and/or sidewalls of the gate-top hard mask layer 222 and the gate spacer layer 226. As shown in FIG. 9, each of the inner spacer features 234 is in direct contact with the recessed sacrificial layers 206 and is disposed vertically (along the Z direction) between two neighboring channel layers 208.

While not explicitly shown, before any of the epitaxial layers are formed, method 100 may include a cleaning process to clean surfaces of the precursor structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

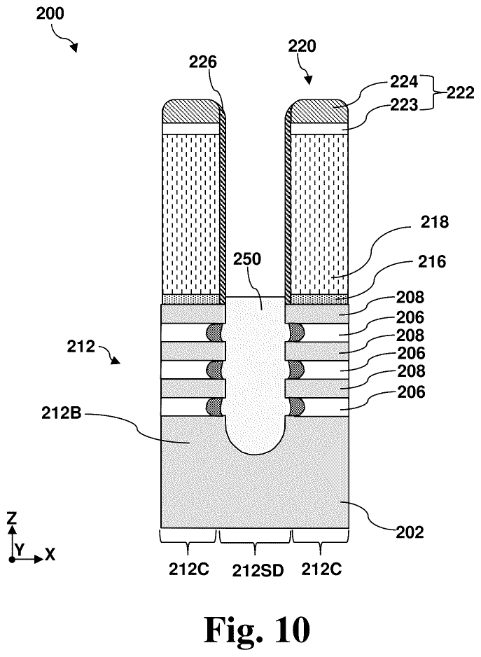

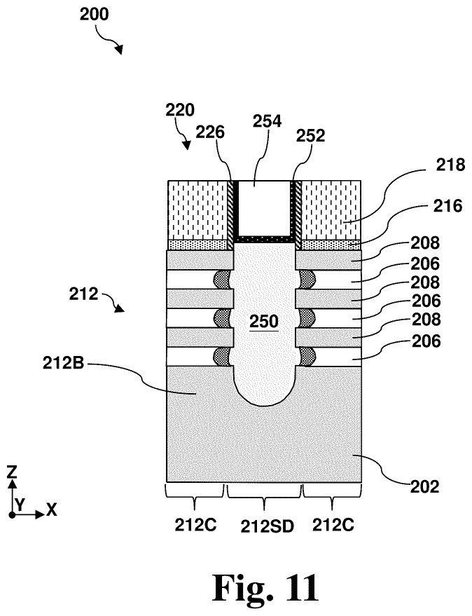

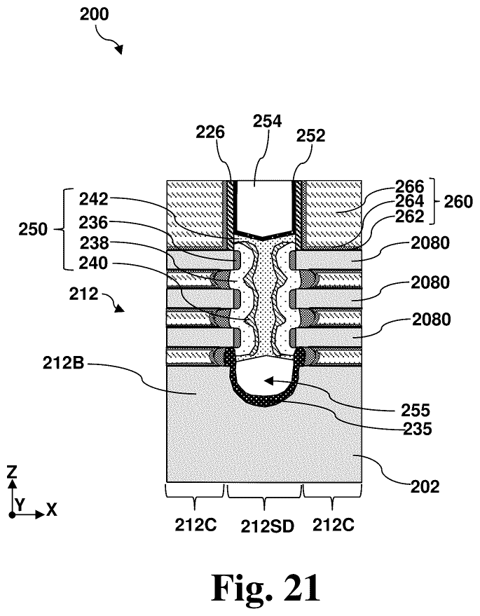

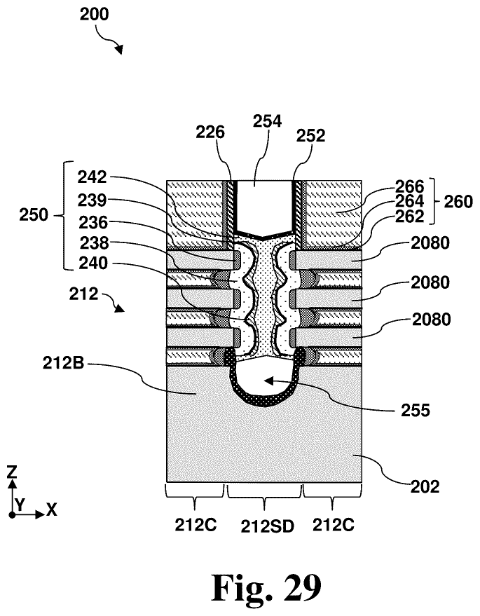

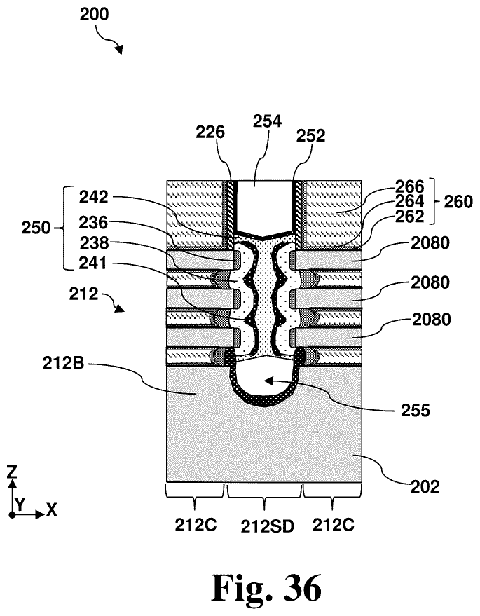

Referring to FIGS. 1 and 10, method 100 includes a block 114 where a source/drain feature 250 is formed over the source/drain region 212SD. In some embodiments represented in the figures, the source/drain feature 250 is an n-type source/drain feature. The source/drain feature 250 includes multiple epitaxial layers and is doped with an n-type dopant, such as phosphorus (P), arsenic (As), antimony (Sb), or a combination thereof. At least one of the multiple epitaxial layers in the source/drain feature 250 includes silicon (Si) and germanium (Ge). At least one of the multiple epitaxial layers in the source/drain feature 250 includes silicon (Si) and is free of germanium (Ge). The source/drain feature 250 may be formed using method 300 in FIG. 15, method 400 in FIG. 22, or method 500 in FIG. 30. It should be understood that the source/drain feature 250 shown in FIG. 10 and the subsequent FIGS. 11-14 may be the source/drain feature 250 in FIG. 21 when method 300 is adopted, the source/drain feature 250 in FIG. 29 when method 400 is adopted, or the source/drain feature 250 in FIG. 36 when method 500 is adopted. That is, the source/drain feature 250 shown in FIGS. 10-14 is a placeholder for the source/drain feature 250 in FIG. 21, the source/drain feature 250 in FIG. 29, or the source/drain feature 250 in FIG. 36.

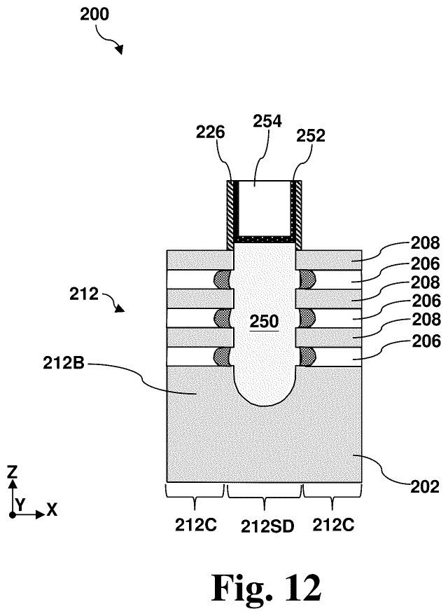

Referring to FIGS. 1 and 11-12, method 100 includes a block 116 where the dummy gate stack 220 is removed. Block 116 may include deposition of a contact etch stop layer (CESL) 252 and an interlayer dielectric (ILD) layer 254 over the source/drain feature 250 (shown in FIG. 11) and removal of the dummy gate stack 220 (shown in FIG. 12). Referring to FIG. 11, the CESL 252 is deposited over the precursor structure 200, including over the source/drain feature 250. The CESL 252 may include silicon nitride or aluminum nitride. In some implementations, the CESL 252 may be deposited using CVD or ALD. The ILD layer 254 is then deposited over the CESL 252. In some embodiments, the ILD layer 254 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 254 may be deposited using CVD, FCVD, spin-on coating, or a suitable deposition technique. After the deposition of the ILD layer 254, the precursor structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. Referring to FIG. 12, the dummy gate stack 220 is removed. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed.

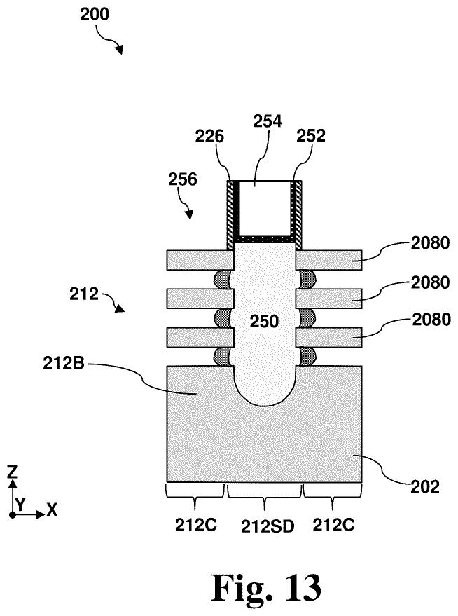

Referring to FIGS. 1 and 13, method 100 includes a block 118 where the plurality of channel layers 208 are released as channel members 2080. After the removal of the dummy gate stack 220, the sacrificial layers 206 between the channel layers 208 in the channel region 212C are selectively removed. The selective removal of the sacrificial layers 206 releases the channel layers 208 (shown in FIG. 12) to form channel members 2080 shown in FIG. 13. The selective removal of the sacrificial layers 206 forms a gate trench 256 that includes spaces between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

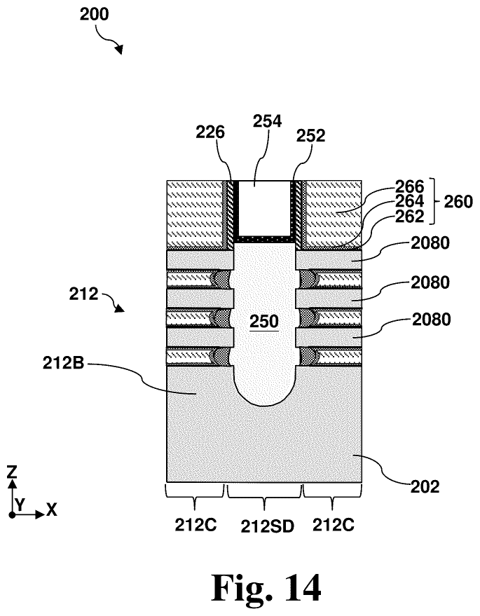

Referring to FIGS. 1 and 14, method 100 includes a block 120 where a gate structure 260 is formed to wrap around each of the channel layers 208 released as channel members 2080. After the release of the channel members 2080, the gate structure 260 is formed to wrap around each of the channel members 2080. In the depicted embodiments, the gate structure 20 includes an interfacial layer 262 interfacing the channel members 2080 and the substrate 202 in the channel region 212C, a gate dielectric layer 264 over the interfacial layer 262, and a gate electrode layer 266 over the gate dielectric layer. The interfacial layer 262 may include a dielectric material such as silicon oxide, hafnium silicate, or silicon oxynitride. The interfacial layer 262 may be formed by chemical oxidation, thermal oxidation, atomic layer deposition (ALD), chemical vapor deposition (CVD), and/or other suitable method. The gate dielectric layer 264 may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. A dielectric constant of the gate dielectric layer 264 is greater than a dielectric constant of the inner spacer features 234, a dielectric constant of the gate spacer layer 226, or a dielectric constant of the isolation feature 214. The gate dielectric layer 264 may be formed by ALD, physical vapor deposition (PVD), CVD, oxidation, and/or other suitable methods.

The gate electrode layer 266 of the gate structure 260 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure includes portions that interpose between channel members 2080 in the channel region 212C. In one embodiment, the gate electrode layer 266 includes a titanium-based material.

Methods 300, 400, and 500 in FIGS. 15, 22, and 30 are example methods for forming the source/drain feature 250 representatively shown in FIGS. 10-14. Method 300 includes formation of a buffer layer to block out-diffusion of dopants. Method 400 includes treating of one of the epitaxial layers before depositing of the buffer layer. Methods 500 includes formation of a doped buffer layer to block out-diffusion of dopants. Methods 300, 400,and 500 are described below in more detail.

Method 300 in FIG. 15 is described below in conjunction with FIGS. 16-21.

Referring to FIGS. 15 and 16, method 300 includes a block 302 where a bottom dielectric layer 235 is formed over the source/drain trench 228. In some embodiments, the bottom dielectric layer 235 includes silicon nitride, silicon carbonitride, silicon oxynitride, or silicon oxycarbonitride. In one embodiment, the bottom dielectric layer 235 is formed along with the inner spacer features 234. In this embodiment, after the dielectric material for the inner spacer features 234 is deposited over the precursor structure 200, an etch back is performed to expose end surfaces of the channel layers 208. Due to restricted access, the etch back does not completely remove the dielectric material at a bottom of the source/drain trench 228, thereby forming the bottom dielectric layer 235 covering the substrate 202 in the source/drain region 212SD. In another embodiment, the bottom dielectric layer 235 is formed in a separate process. After the inner spacer features 234 are formed, a dielectric material for the bottom dielectric layer 235 is conformally deposited over the source/drain trench 228. Afterwards, a dummy layer, such as a bottom antireflective coating (BARC) layer, is deposited over the dielectric material for the bottom dielectric layer 235. The dummy layer is then etched back to have a reduced depth. With the dummy layer protecting a bottom portion of the dielectric material, the exposed dielectric material is selectively removed. After the dummy layer is selectively removed by ashing or selective etching, the leftover bottom portion of the dielectric material becomes the bottom dielectric layer 235. The bottom dielectric layer 235 completely covers the surfaces of the substrate 202 to prevent epitaxial deposition on the substrate 202. In some embodiments represented in FIG. 16, the bottom dielectric layer 235 may partially or even completely cover sidewalls of the bottommost inner spacer features 234.

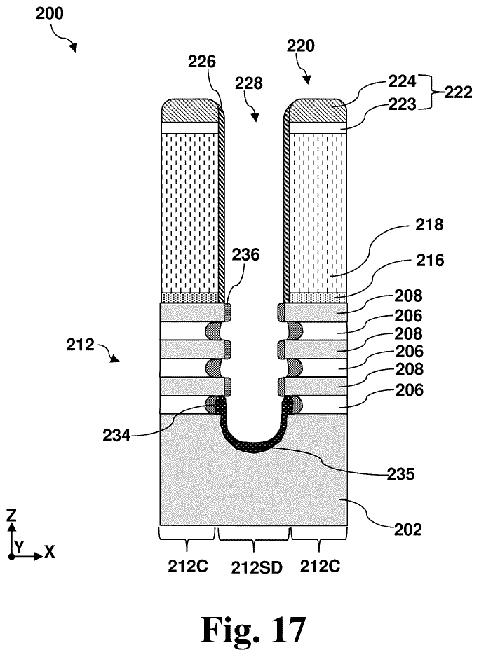

Referring to FIGS. 15 and 17, method 300 includes a block 304 where a first epitaxial layer 236 is formed over the source/drain trench 228. With the bottom dielectric layer 235 covering the substrate 202, end surfaces of the channel layers 208 are the only exposed semiconductor surfaces. This allows the first epitaxial layer 236 to be selectively and epitaxially deposited on the exposed semiconductor surfaces of the channel layers 208. To ensure selective deposition, the first epitaxial layer 236 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the first epitaxial layer 236 primarily on exposed semiconductor surfaces and the etch component (or etch cycles) removes the first epitaxial layer 236 deposited on non-semiconductor surfaces. In some embodiments, the selective deposition of the first epitaxial layer 236 may include use of vapor-phase epitaxy (VPE), ultra-high vacuum CVD (UHV-CVD), or molecular beam epitaxy (MBE), with a process pressure between about 200 Torr and about 300 Torr and a process temperature between about 600° C. and about 700° C. In the depicted embodiments, surfaces of the gate spacer layer 226, the inner spacer features 234, and the bottom dielectric layer 235 may be completely free of the first epitaxial layer 236 with precise process control.

In some embodiments, the first epitaxial layer 236 may include silicon (Si) and an n-type dopant having a greater molecular weight than phosphorus (P). The high molecular weight n-type dopant provides the first epitaxial layer 236 with an improved ability to block diffusion of phosphorus (P). In some implementations, a precursor used for deposition of the first epitaxial layer 236 includes halogen silane, such as dichlorosilane (DCS). The n-type dopant that is in-situ doped into the first epitaxial layer 236 may include arsenic (As), antimony (Sb), or a combination thereof. In one embodiment, the first epitaxial layer 236 is doped with arsenic (As).

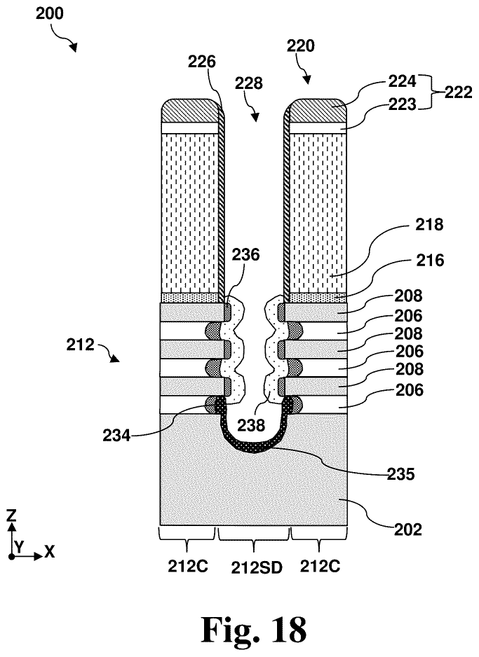

Referring to FIGS. 15 and 18, method 300 includes a block 306 where a second epitaxial layer 238 is deposited over the first epitaxial layer 236. At block 306, the second epitaxial layer 238 is selectively deposited from surfaces of the first epitaxial layer 236. Like the first epitaxial layer 236, the second epitaxial layer 238 includes silicon (Si) and may be formed using a halogen silane, such as dichlorosilane (DCS). Different from the first epitaxial layer 236, the second epitaxial layer 238 is doped with phosphorus (P), rather than a higher molecular weight n-type dopant. In some embodiments, the deposition of the second epitaxial layer 238 may include use of vapor-phase epitaxy (VPE), ultra-high vacuum CVD (UHV-CVD), or molecular beam epitaxy (MBE), with a process pressure between about 200 Torr and about 300 Torr and a process temperature between about 600° C. and about 700° C. The second epitaxial layer 238 serves more as a transition layer than a heavily doped highly conductive layer. For that reason, a doping concentration in the second epitaxial layer 238 is smaller than that in a third epitaxial layer 242 (to be described further below). In some embodiments, the second epitaxial layer 238 merges over the inner spacer features 234 without contacting them. In some embodiments represented in FIG. 18, the second epitaxial layer 238 not only merges over the inner spacer features 234 but also interfaces the inner spacer features 234.

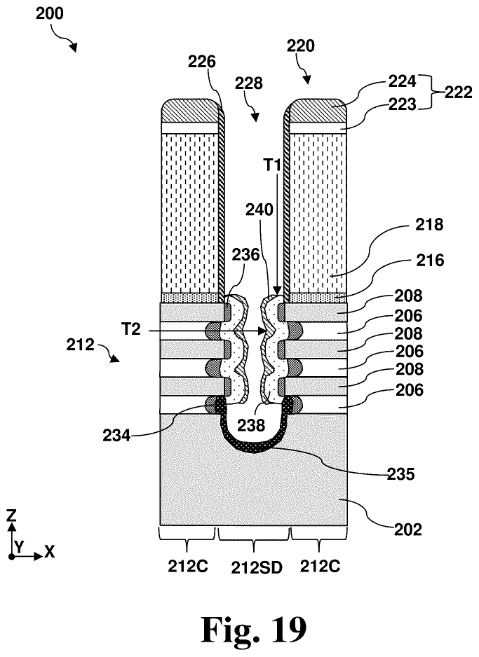

Referring to FIGS. 15 and 19, method 300 includes a block 308 where a buffer layer 240 is deposited over the second epitaxial layer 238. In some embodiments, a halogen silane, such as dichlorosilane (DCS), is used to deposit the buffer layer 240. In some embodiments represented in FIG. 19, the buffer layer 240 is undoped or not intentionally doped to serve as a diffusion blocking layer or diffusion buffering layer. That is, the buffer layer 240 may include undoped silicon (Si). Because the buffer layer 240 is intended to block more of the lateral dopant diffusion, the deposition process of the buffer layer 240 is configured to be deposited along sidewalls of the second epitaxial layer 238. To achieve that, the buffer layer 240 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the buffer layer 240 primarily on exposed surfaces of the second epitaxial layer 238 and the etch component (or etch cycles) removes the buffer layer 240 from top-facing surfaces of the second epitaxial layer 238. As shown in FIG. 19, the buffer layer 240 over a top-face surface of the second epitaxial layer 238 may have a first thickness T1 and the buffer layer 240 along a sidewall of the second epitaxial layer 238 may have a second thickness T2. As the buffer layer 240 is undoped, it does not possess high electrical conductivity. To ensure that the buffer layer 240 does not increase the resistance of the source/drain feature 250, the second thickness T2 is greater than the first thickness T1. In some embodiments, the deposition of the buffer layer 240 may include use of vapor-phase epitaxy (VPE), ultra-high vacuum CVD (UHV-CVD), or molecular beam epitaxy (MBE), with a process pressure between about 200 Torr and about 300 Torr and a process temperature between about 700° C. and about 800° C. It is noted that the process temperature for the deposition of the buffer layer 240 is higher than that for the deposition of the other epitaxial layers. The higher process temperature helps ensure a better crystalline structure and quality of the buffer layer 240 such that it can better block diffusion of dopants. In some embodiments, the buffer layer 240 includes an average thickness between 2 nm and about 4 nm. The second thickness T2 is smaller than 3 nm or may be zero. This thickness range is not trivial. When the average thickness of the buffer layer 240 is less than 2 nm, it may not possess sufficient diffusion blocking capability. When the average thickness of the buffer layer 240 is more than 4 nm, it may occupy space available for highly conductive epitaxial layers and cause high resistance in the source/drain feature 250.

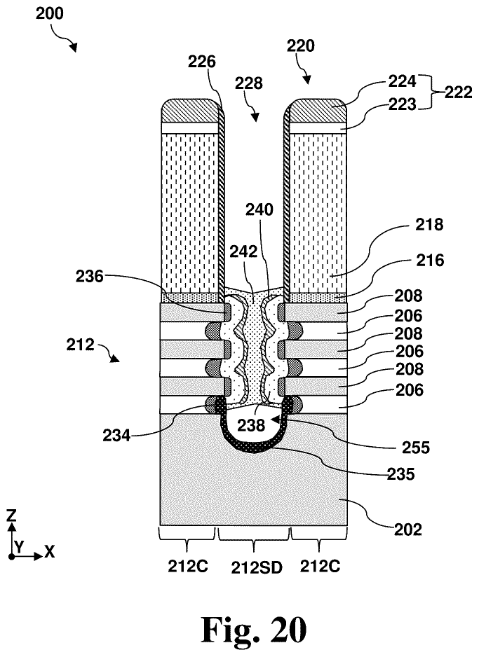

Referring to FIGS. 15 and 20, method 300 includes a block 310 where a third epitaxial layer 242 is deposited over the buffer layer 240. At block 310, the third epitaxial layer 242 is selectively deposited from surfaces of the buffer layer 240. Like the second epitaxial layer 238, the third epitaxial layer 242 includes silicon (Si) and may be formed using a halogen silane, such as dichlorosilane (DCS). The third epitaxial layer 242 is doped with phosphorus (P) and a doping concentration of phosphorus (P) in the third epitaxial layer 242 may be between about 3.5×10²¹ atoms/cm³ (or 3.5 E21 atoms/cm³) and about 4×10²¹ atoms/cm³ (or 4 E21 atoms/cm³). Such a high phosphorus doping concentration may be considered too high without the presence of the buffer layer 240 as the concentration gradient can drive the out-diffusion of phosphorus (P) into the second epitaxial layer 238. The loss of the phosphorus doping concentration in the third epitaxial layer 242 may lead to increased deviation of threshold voltages (Vt-Sigma) or increased resistance (R). In some embodiments, the deposition of the third epitaxial layer 242 may include use of vapor-phase epitaxy (VPE), ultra-high vacuum CVD (UHV-CVD), or molecular beam epitaxy (MBE), with a process pressure between about 200 Torr and about 300 Torr and a process temperature between about 600° C. and about 700° C.

As shown in FIG. 20, the third epitaxial layer 242 extends vertically through the vertical channel defined by the buffer layer 240 to be exposed in a void 255 defined by the third epitaxial layer 242 and the bottom dielectric layer 235. The third epitaxial layer 242 also extends between the horizontally-aligned channel layers 208 that will be released as channel members 2080 shown in FIG. 14. The third epitaxial layer 242 is spaced apart from the end surfaces of the channel layers 208 by the buffer layer 240, the second epitaxial layer 238, and the first epitaxial layer 236. Additionally, the third epitaxial layer 242 may interface top-facing surfaces of the second epitaxial layer 238 when the buffer layer 240 on the top-facing surfaces of the second epitaxial layer 238 is thin or non-existent.

FIG. 21 illustrates a semiconductor device 200 when method 300 is adopted to form the source/drain feature 250 described above with respect to method 100. After the third epitaxial layer 242 is formed, the source/drain feature 250 is substantially formed. In this regard, the source/drain feature 250 includes the first epitaxial layer 236, the second epitaxial layer 238, the buffer layer 240, and the third epitaxial layer 242. The bottom dielectric layer 235 helps define the shape and profile of the source/drain feature 250 shown in FIG. 21. In some embodiments shown in FIG. 21, the third epitaxial layer 242 includes a middle recess and the CESL 252 and the ILD 254 track the top profile of the third epitaxial layer 242.

Method 400 in FIG. 22 is described below in conjunction with FIGS. 23-29.

Referring to FIGS. 22 and 23, method 400 includes a block 402 where a bottom dielectric layer 235 is formed over the source/drain trench. Operations at block 402 may be substantially similar to those at block 302 described above. A detailed description of the operations at block 402 is therefore omitted for brevity.

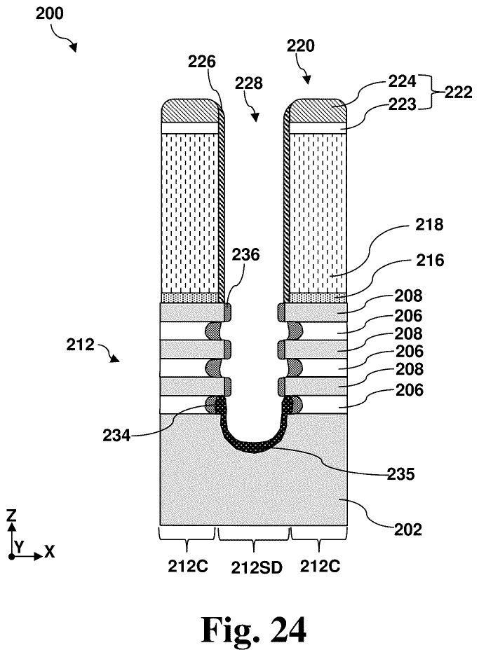

Referring to FIGS. 22 and 24, method 400 includes a block 404 where a first epitaxial layer 236 is deposited over the source/drain trench. Operations at block 404 may be substantially similar to those at block 304 described above. A detailed description of the operations at block 404 is therefore omitted for brevity.

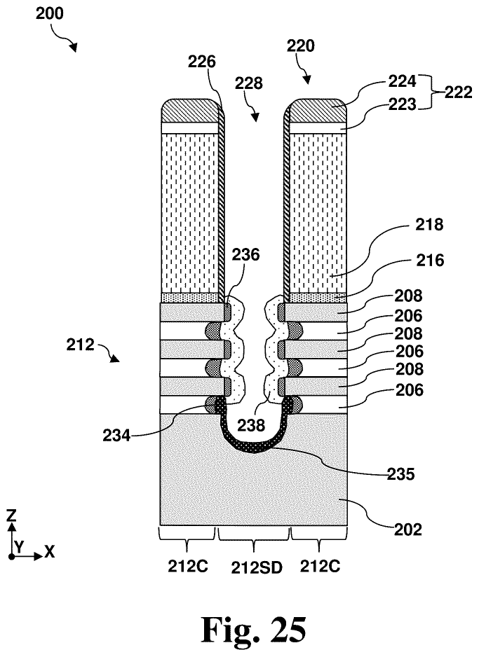

Referring to FIGS. 22 and 25, method 400 includes a block 406 where a second epitaxial layer 238 is deposited over the first epitaxial layer 236. Operations at block 406 may be substantially similar to those at block 306 described above. A detailed description of the operations at block 406 is therefore omitted for brevity.

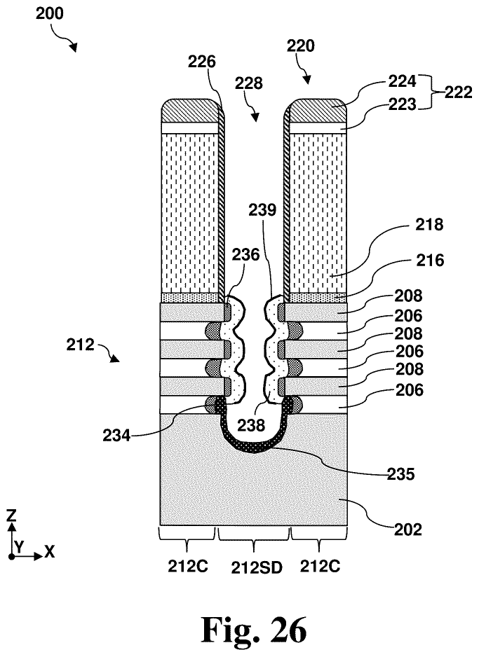

Referring to FIGS. 22 and 26, method 400 includes a block 408 where the second epitaxial layer 238 is treated with an arsenic-containing gas. In some embodiments, the arsenic-containing gas includes arsenic hydride (or arsine). At block 408, the treatment with the arsenic-containing gas may be considered an ALD process or a physical vapor deposition (PVD) and may deposit an arsenic-containing layer 239. Because the arsenic-containing layer 239 may impact electrical conductivity or formation of the third epitaxial layer 242, it may be a single atomic layer. In some instances, the arsenic-containing layer 239 includes a thickness between 0.5 nm and about 1.5 nm. The arsenic-containing layer 239 includes silicon arsenide (SiAs) or arsenic-doped silicon.

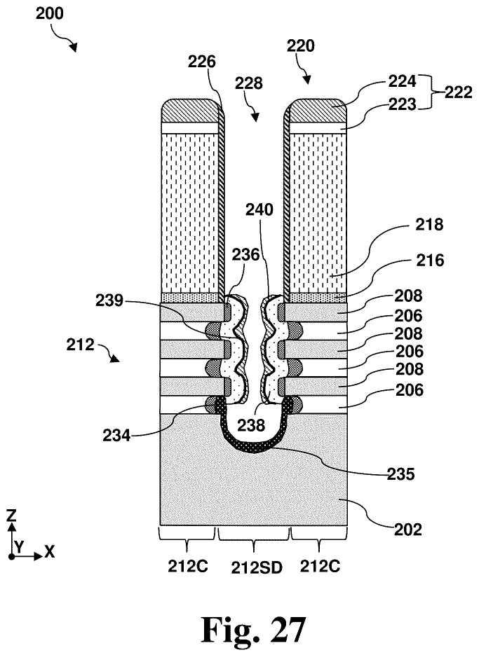

Referring to FIGS. 22 and 27, method 400 includes a block 410 where a buffer layer 240 is deposited over the second epitaxial layer 238. In some embodiments, a halogen silane, such as dichlorosilane (DCS), is used to deposit the buffer layer 240 over the arsenic-containing layer 239. In some embodiments represented in FIG. 27, the buffer layer 240 is undoped or not intentionally doped to serve as a diffusion blocking layer or diffusion buffering layer. That is, the buffer layer 240 may include undoped silicon (Si). Because the buffer layer 240 is intended to block more of the lateral dopant diffusion, the deposition process of the buffer layer 240 is configured to be deposited along sidewalls of the second epitaxial layer 238. To achieve that, the buffer layer 240 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the buffer layer 240 primarily on exposed surfaces of the arsenic-containing layer 239 and the etch component (or etch cycles) removes the buffer layer 240 from top-facing surfaces of the second epitaxial layer 238. In some embodiments, the deposition of the buffer layer 240 may include use of vapor-phase epitaxy (VPE), ultra-high vacuum CVD (UHV-CVD), or molecular beam epitaxy (MBE), with a process pressure between about 200 Torr and about 300 Torr and a process temperature between about 700° C. and about 800° C. It is noted that the process temperature for the deposition of the buffer layer 240 is higher than that for the deposition of the other epitaxial layers. The higher process temperature helps ensure a better crystalline structure and quality of the buffer layer 240 such that it can better block diffusion of dopants. When method 400 is adopted, the buffer layer 240 includes an average thickness between 1.5 nm and about 2.5 nm as the arsenic-containing layer 239 may also account for another 0.5 nm to 1.5 nm of thickness. The corresponding thickness reduction for the buffer layer 240 ensures that the most electrically conductive third epitaxial layer 242 occupies the majority of the volume of the source/drain feature 250.

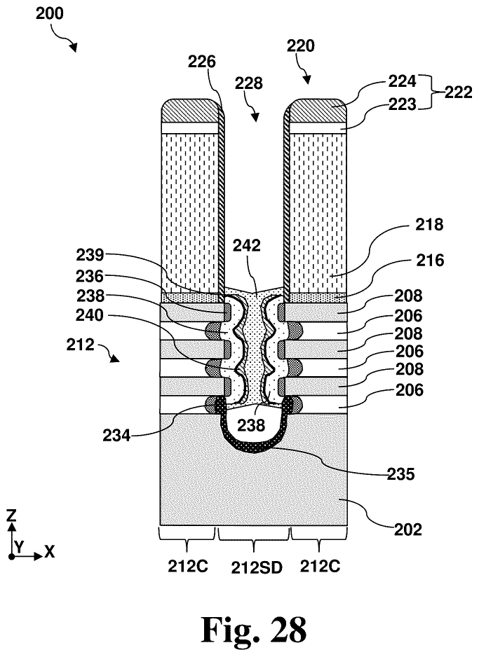

Referring to FIGS. 22 and 28, method 400 includes a block 412 where a third epitaxial layer 242 is deposited over the buffer layer 240. Operations at block 412 may be substantially similar to those at block 310 described above. A detailed description of the operations at block 412 is therefore omitted for brevity. When method 400 is adopted, the arsenic-containing layer 239 and the buffer layer 240 may work in synergy to provide even better diffusion prevention than the buffer layer 240 alone. In some embodiments, when method 400 is adopted, a doping concentration of phosphorus in the third epitaxial layer 242 may be between about 4×10²¹ atoms/cm³ (or 4 E21 atoms/cm³) and about 4.5 ×10²¹ atoms/cm³ (or 4.5 E21 atoms/cm³). This doping concentration is higher than the counterpart when method 300 is adopted.

As shown in FIG. 28, the third epitaxial layer 242 extends vertically through the vertical channel defined by the buffer layer 240 to be exposed in a void 255 defined by the third epitaxial layer 242 and the bottom dielectric layer 235. The third epitaxial layer 242 also extends between the horizontally-aligned channel layers 208 that will be released as channel members 2080 shown in FIG. 14. The third epitaxial layer 242 is spaced apart from the end surfaces of the channel layers 208 by the buffer layer 240, the arsenic-containing layer 239, the second epitaxial layer 238, and the first epitaxial layer 236. Additionally, the third epitaxial layer 242 may interface top-facing surfaces of the arsenic-containing layer 239 when the buffer layer 240 on the top-facing surfaces of the arsenic-containing layer 239 is thin or non-existent.

FIG. 29 illustrates a semiconductor device 200 when method 400 is adopted to form the source/drain feature 250 described above with respect to method 100. After the third epitaxial layer 242 is formed, the source/drain feature 250 is substantially formed. In this regard, the source/drain feature 250 includes the first epitaxial layer 236, the second epitaxial layer 238, the arsenic-containing layer 239, the buffer layer 240, and the third epitaxial layer 242. The bottom dielectric layer 235 helps define the shape and profile of the source/drain feature 250 shown in FIG. 29. In some embodiments shown in FIG. 29, the third epitaxial layer 242 includes a middle recess and the CESL 252 and the ILD 254 track the top profile of the third epitaxial layer 242.

Method 500 in FIG. 30 is described below in conjunction with FIGS. 31-36.

Referring to FIGS. 30 and 31, method 500 includes a block 502 where a bottom dielectric layer 235 is formed over the source/drain trench 228. Operations at block 502 may be substantially similar to those at block 302 described above. A detailed description of the operations at block 502 is therefore omitted for brevity.

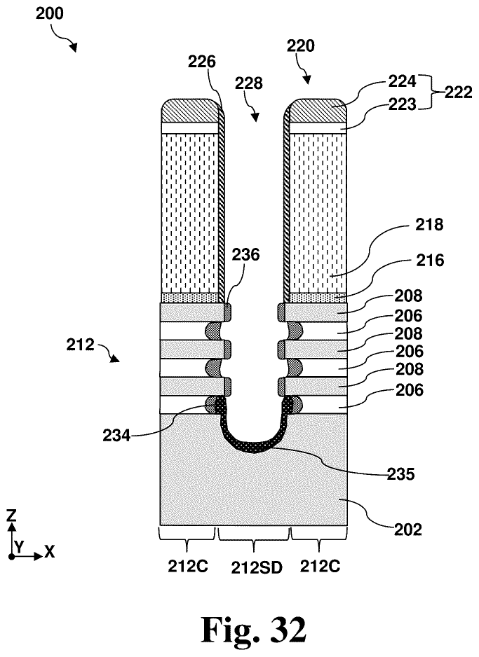

Referring to FIGS. 30 and 32, method 500 includes a block 504 where a first epitaxial layer 236 is formed over the source/drain trench 228. Operations at block 504 may be substantially similar to those at block 304 described above. A detailed description of the operations at block 502 is therefore omitted for brevity.

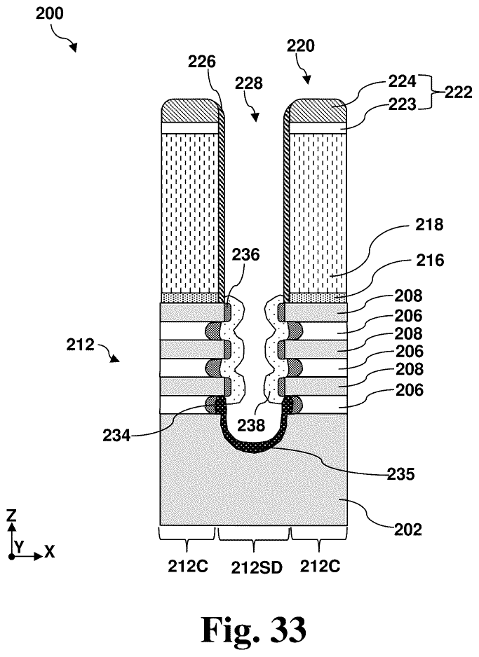

Referring to FIGS. 30 and 33, method 500 includes a block 506 where a second epitaxial layer 238 is formed over the first epitaxial layer 236. Operations at block 506 may be substantially similar to those at block 306 described above. A detailed description of the operations at block 506 is therefore omitted for brevity.

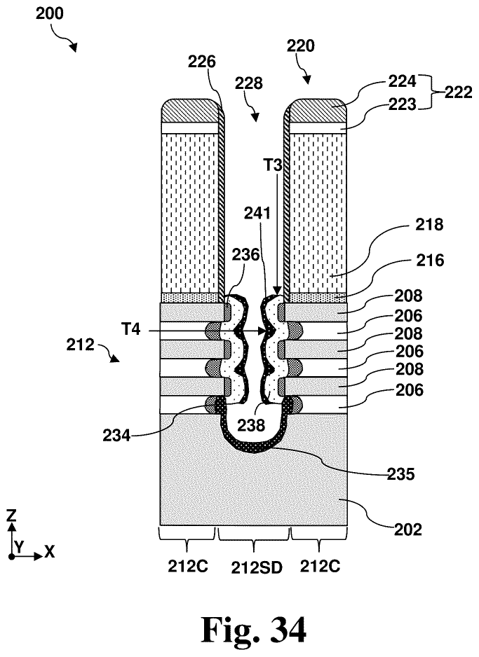

Referring to FIGS. 30 and 34, method 500 includes a block 508 where a doped buffer layer 241 is formed over the second epitaxial layer 238. In some embodiments, a silicon source gas and an arsenic source gas are used to deposit the doped buffer layer 241. In some embodiments, the silicon source gas may include halogen silane, such as dichlorosilane (DCS) and the arsenic source gas may include arsenic hydride (i.e., arsine). Because the doped buffer layer 241 is intended to block more of the lateral dopant diffusion, the deposition process of the doped buffer layer 241 is configured to be deposited along sidewalls of the second epitaxial layer 238. To achieve that, the doped buffer layer 241 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the doped buffer layer 241 primarily on exposed surfaces of the second epitaxial layer 238 and the etch component (or etch cycles) removes the doped buffer layer 241 from top-facing surfaces of the second epitaxial layer 238. As shown in FIG. 34, the doped buffer layer 241 over a top-face surface of the second epitaxial layer 238 may have a third thickness T3 and the doped buffer layer 241 along a sidewall of the second epitaxial layer 238 may have a fourth thickness T2. As the doped buffer layer 241 is configured to block or prevent diffusion, it does not possess high electrical conductivity. To ensure that the doped buffer layer 241 does not increase the resistance of the source/drain feature 250, the fourth thickness T4 is greater than the third thickness T3. In some embodiments, the deposition of the doped buffer layer 241 may include use of CVD, ultra-high vacuum CVD (UHV-CVD), or ALD, with a process pressure between about 200 Torr and about 300 Torr and a process temperature between about 600° C. and about 700° C. It is noted that the process temperature for the deposition of the doped buffer layer 241 is comparable with that for the deposition of the other epitaxial layers.

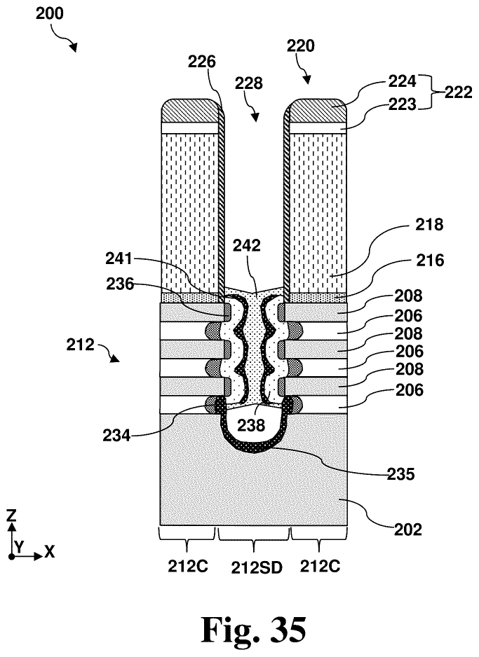

Referring to FIGS. 30 and 35, method 500 includes a block 510 where a third epitaxial layer 242 over the doped buffer layer 241. At block 510, the third epitaxial layer 242 is selectively deposited from surfaces of the doped buffer layer 241. Like the second epitaxial layer 238, the third epitaxial layer 242 includes silicon (Si) and may be formed using a halogen silane, such as dichlorosilane (DCS). The third epitaxial layer 242 is doped with phosphorus (P) and a doping concentration of phosphorus (P) in the third epitaxial layer 242 may be between about 5×10²¹ atoms/cm³ (or 5 E21 atoms/cm³) and about 5.5×10²¹ atoms/cm³ (or 5.5 E21 atoms/cm³). This doping concentration is higher than the counterpart when method 300 or method 400 is adopted. Such a high phosphorus doping concentration may be considered too high without the presence of the doped buffer layer 241 as the concentration gradient can drive the out-diffusion of phosphorus (P) into the second epitaxial layer 238. The loss of the phosphorus doping concentration in the third epitaxial layer 242 may lead to increased deviation of threshold voltages (Vt-Sigma) or increased resistance (R). In some embodiments, the deposition of the third epitaxial layer 242 may include use of vapor-phase epitaxy (VPE), ultra-high vacuum CVD (UHV-CVD), or molecular beam epitaxy (MBE), with a process pressure between about 200 Torr and about 300 Torr and a process temperature between about 600° C. and about 700° C.

As shown in FIG. 35, the third epitaxial layer 242 extends vertically through the vertical channel defined by the doped buffer layer 241 to be exposed in a void 255 defined by the third epitaxial layer 242 and the bottom dielectric layer 235. The third epitaxial layer 242 also extends between the horizontally-aligned channel layers 208 that will be released as channel members 2080 shown in FIG. 14. The third epitaxial layer 242 is spaced apart from the end surfaces of the channel layers 208 by the doped buffer layer 240, the second epitaxial layer 238, and the first epitaxial layer 236. Additionally, the third epitaxial layer 242 may interface top-facing surfaces of the second epitaxial layer 238 when the doped buffer layer 241 on the top-facing surfaces of the second epitaxial layer 238 is thin or non-existent.

FIG. 36 illustrates a semiconductor device 200 when method 500 is adopted to form the source/drain feature 250 described above with respect to method 100. After the third epitaxial layer 242 is formed, the source/drain feature 250 is substantially formed. In this regard, the source/drain feature 250 includes the first epitaxial layer 236, the second epitaxial layer 238, the doped buffer layer 241, and the third epitaxial layer 242. The bottom dielectric layer 235 helps define the shape and profile of the source/drain feature 250 shown in FIG. 36. In some embodiments shown in FIG. 36, the third epitaxial layer 242 includes a middle recess and the CESL 252 and the ILD 254 track the top profile of the third epitaxial layer 242.

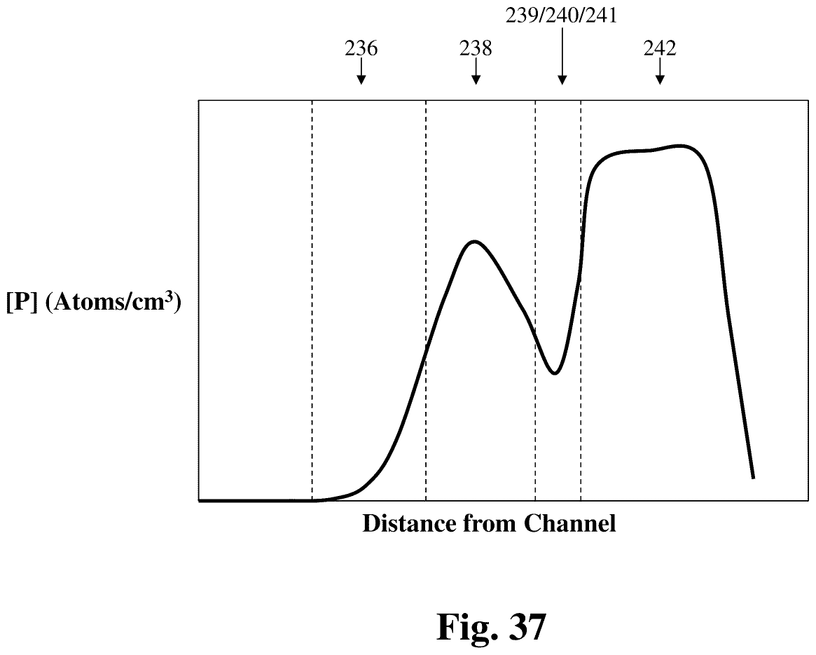

FIG. 37 illustrates phosphorus concentration from an end surface of a channel member 2080. In the illustrated example, phosphorus in the second epitaxial layer 238 may diffuse into the originally arsenic-free first epitaxial layer, causing an increase of phosphorus near an interface between the first epitaxial layer 236 and the second epitaxial layer 238. The buffer layer 240 in method 300, the arsenic-containing layer 239 and the buffer layer in method 400, or the doped buffer layer 241 in method 500 functions to prevent or block phosphorus diffusion from the third epitaxial layer 242 towards the channel (i.e., the channel members 2080). It can be seen that first epitaxial layer 236 and the diffusion blocking layer (i.e., the buffer layer 240 in method 300, the arsenic-containing layer 239 and the buffer layer in method 400, or the doped buffer layer 241 in method 500) help trap and lock the phosphorus in the second epitaxial layer 238. The diffusion blocking layer (i.e., the buffer layer 240 in method 300, the arsenic-containing layer 239 and the buffer layer in method 400, or the doped buffer layer 241 in method 500) also help maintain and lock the phosphorus concentration in the third epitaxial layer 242.

In one exemplary aspect, the present disclosure is directed to a method. The method includes forming over a substrate a semiconductor stack that includes a plurality of first semiconductor layers interleaved by a plurality of second semiconductor layers, patterning the semiconductor stack and a portion of the substrate to form a fin-shaped structure, forming a dummy gate stack over a channel region of the fin-shaped structure, recessing a source/drain region of the fin-shaped structure to form a source/drain recess, selectively recessing the plurality of second semiconductor layers to form inner spacer recesses, forming inner spacer features in the inner spacer recesses, depositing a first epitaxial layer over the source/drain recess, depositing a second epitaxial layer over the first epitaxial layer, depositing a buffer layer over the second epitaxial layer, depositing a third epitaxial layer over the buffer layer, depositing a dielectric layer over the third epitaxial layer, removing the dummy gate stack, selectively removing the plurality of second semiconductor layers to release the plurality of first semiconductor layers as channel members, and forming a gate structure to wrap around each of the channel members. The gate structure includes a gate dielectric layer and a gate electrode over the gate dielectric layer. A dielectric constant of the gate dielectric layer is greater than a dielectric constant of the inner spacer features.

In some embodiments, the first epitaxial layer includes silicon and a first dopant, the second epitaxial layer includes silicon and a second dopant, and the first dopant is different from the second dopant. In some embodiments, the first dopant includes arsenic (As) and the second dopant includes phosphorus (P). In some implementations, the depositing of the of the buffer layer includes depositing an undoped silicon. In some instances, the depositing of the second epitaxial layer includes a first deposition temperature and the depositing of the buffer layer includes a second deposition temperature greater than the first deposition temperature. In some embodiments, the first deposition temperature is between about 600° C. and about 700° C. and the second deposition temperature is between about 700° C. and about 800° C. In some embodiments, the method further includes, before the depositing of the buffer layer, treating the second epitaxial layer with an arsenic-containing gas. In some embodiments, the arsenic-containing gas includes arsenic hydride. In some embodiments, the method further includes before the depositing of the first epitaxial layer, forming a bottom dielectric layer over a bottom surface of the source/drain recess.

In another exemplary aspect, the present disclosure is directed to a method. The method includes forming a semiconductor stack over a substrate, the semiconductor stack including a plurality of first semiconductor layers interleaved by a plurality of second semiconductor layers, patterning the semiconductor stack and a portion of the substrate to form a fin-shaped structure, the fin-shaped structure including a base portion formed from the substrate, forming an isolation structure over the substrate to interface sidewalls of the base portion, forming a dummy gate stack over a channel region of the fin-shaped structure, recessing a source/drain region of the fin-shaped structure to form a source/drain recess, selectively recessing the plurality of second semiconductor layers to form inner spacer recesses, forming inner spacer features in the inner spacer recesses, depositing a first epitaxial layer over the source/drain recess, depositing a second epitaxial layer over the first epitaxial layer, depositing a buffer layer over the second epitaxial layer, depositing a third epitaxial layer over the buffer layer, depositing a dielectric layer over the third epitaxial layer, removing the dummy gate stack, selectively removing the plurality of second semiconductor layers to release the plurality of first semiconductor layers as channel members, and forming a gate structure to wrap around each of the channel members. A composition of the buffer layer is different from that of the second epitaxial layer or that of the third epitaxial layer and the isolation structure includes an oxide-based material.

In some embodiments, the first epitaxial layer includes silicon and a first dopant and the second epitaxial layer, the third epitaxial layer include silicon and a second dopant, and the first dopant is different from the second dopant. In some embodiments, the first dopant includes arsenic (As) and the second dopant includes phosphorus (P). In some embodiments, the depositing of the second epitaxial layer includes a first deposition temperature and the depositing of the buffer layer includes a second deposition temperature greater than the first deposition temperature. In some implementations, the depositing of the of the buffer layer includes depositing an undoped silicon. In some embodiments, the method further includes before the depositing of the buffer layer, treating the second epitaxial layer with an arsenic-containing gas. In some implementations, a thickness of the buffer layer is greater than a thickness of the first epitaxial layer.

In yet another exemplary aspect, the present disclosure is directed to a method. The method includes forming a semiconductor stack over a substrate, the semiconductor stack including a plurality of first semiconductor layers interleaved by a plurality of second semiconductor layers, patterning the semiconductor stack and a portion of the substrate to form a fin-shaped structure, forming a dummy gate stack over a channel region of the fin-shaped structure, recessing a source/drain region of the fin-shaped structure to form a source/drain recess, selectively recessing the plurality of second semiconductor layers to form inner spacer recesses, forming inner spacer features in the inner spacer recesses, forming a bottom dielectric layer over a bottom surface of the source/drain recess, after the forming of the bottom dielectric layer, depositing a first epitaxial layer over the source/drain recess, depositing a second epitaxial layer over the first epitaxial layer, depositing a buffer layer over the second epitaxial layer, depositing a third epitaxial layer over the buffer layer, depositing a dielectric layer over the third epitaxial layer, removing the dummy gate stack, selectively removing the plurality of second semiconductor layers to release the plurality of first semiconductor layers as channel members, and forming a gate structure to wrap around each of the channel members. The gate structure includes a gate dielectric layer and a gate electrode over the gate dielectric layer. The gate electrode includes a titanium-based material.

In some embodiments, the depositing of the buffer layer includes use of dichlorosilane (DCS). In some embodiments, the method further includes before the depositing of the buffer layer, treating the second epitaxial layer with an arsenic-containing gas. In some implementations, the arsenic-containing gas includes arsenic hydride.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor stack over a substrate, the semiconductor stack comprising a plurality of first semiconductor layers interleaved by a plurality of second semiconductor layers;
patterning the semiconductor stack and a portion of the substrate to form a fin-shaped structure;
forming a dummy gate stack over a channel region of the fin-shaped structure;
recessing a source/drain region of the fin-shaped structure to form a source/drain recess;
selectively recessing the plurality of second semiconductor layers to form inner spacer recesses;
forming inner spacer features in the inner spacer recesses;
depositing a first epitaxial layer over the source/drain recess;
depositing a second epitaxial layer over the first epitaxial layer;
depositing a buffer layer over the second epitaxial layer;
depositing a third epitaxial layer over the buffer layer;
depositing a dielectric layer over the third epitaxial layer;
removing the dummy gate stack;
selectively removing the plurality of second semiconductor layers to release the plurality of first semiconductor layers as channel members; and
forming a gate structure to wrap around each of the channel members,
wherein the gate structure comprises a gate dielectric layer and a gate electrode over the gate dielectric layer,
wherein a dielectric constant of the gate dielectric layer is greater than a dielectric constant of the inner spacer features.

2. The method of claim 1,
wherein the first epitaxial layer comprises silicon and a first dopant,
wherein the second epitaxial layer comprises silicon and a second dopant,
wherein the first dopant is different from the second dopant.

3. The method of claim 2,
wherein the first dopant comprises arsenic (As),
wherein the second dopant comprises phosphorus (P).

4. The method of claim 1, wherein the depositing of the of the buffer layer comprises depositing an undoped silicon.

5. The method of claim 4,
wherein the depositing of the second epitaxial layer comprises a first deposition temperature,
wherein the depositing of the buffer layer comprises a second deposition temperature greater than the first deposition temperature.

6. The method of claim 5,
wherein the first deposition temperature is between about 600° C. and about 700° C.,
wherein the second deposition temperature is between about 700° C. and about 800° C.

7. The method of claim 4, further comprising:
before the depositing of the buffer layer, treating the second epitaxial layer with an arsenic-containing gas.

8. The method of claim 7, wherein the arsenic-containing gas comprises arsenic hydride.

9. The method of claim 1, further comprising:
before the depositing of the first epitaxial layer, forming a bottom dielectric layer over a bottom surface of the source/drain recess.

10. A method, comprising:
forming a semiconductor stack over a substrate, the semiconductor stack comprising a plurality of first semiconductor layers interleaved by a plurality of second semiconductor layers;
patterning the semiconductor stack and a portion of the substrate to form a fin-shaped structure, the fin-shaped structure comprising a base portion formed from the substrate;
forming an isolation structure over the substrate to interface sidewalls of the base portion;
forming a dummy gate stack over a channel region of the fin-shaped structure;
recessing a source/drain region of the fin-shaped structure to form a source/drain recess;
selectively recessing the plurality of second semiconductor layers to form inner spacer recesses;
forming inner spacer features in the inner spacer recesses;
depositing a first epitaxial layer over the source/drain recess;
depositing a second epitaxial layer over the first epitaxial layer;
depositing a buffer layer over the second epitaxial layer;
depositing a third epitaxial layer over the buffer layer;
depositing a dielectric layer over the third epitaxial layer;
removing the dummy gate stack;
selectively removing the plurality of second semiconductor layers to release the plurality of first semiconductor layers as channel members; and
forming a gate structure to wrap around each of the channel members,
wherein a composition of the buffer layer is different from that of the second epitaxial layer or that of the third epitaxial layer,
wherein the isolation structure comprises an oxide-based material.

11. The method of claim 10,
wherein the first epitaxial layer comprises silicon and a first dopant,
wherein the second epitaxial layer and the third epitaxial layer comprise silicon and a second dopant,
wherein the first dopant is different from the second dopant.

12. The method of claim 11,
wherein the first dopant comprises arsenic (As),
wherein the second dopant comprises phosphorus (P).

13. The method of claim 10,
wherein the depositing of the second epitaxial layer comprises a first deposition temperature,
wherein the depositing of the buffer layer comprises a second deposition temperature greater than the first deposition temperature.

14. The method of claim 10, wherein the depositing of the of the buffer layer comprises depositing an undoped silicon.

15. The method of claim 10, further comprising:
before the depositing of the buffer layer, treating the second epitaxial layer with an arsenic-containing gas.

16. The method of claim 10, wherein a thickness of the buffer layer is greater than a thickness of the first epitaxial layer.

17. A method, comprising:
forming a semiconductor stack over a substrate, the semiconductor stack comprising a plurality of first semiconductor layers interleaved by a plurality of second semiconductor layers;
patterning the semiconductor stack and a portion of the substrate to form a fin-shaped structure;
forming a dummy gate stack over a channel region of the fin-shaped structure;
recessing a source/drain region of the fin-shaped structure to form a source/drain recess;
selectively recessing the plurality of second semiconductor layers to form inner spacer recesses;
forming inner spacer features in the inner spacer recesses;
forming a bottom dielectric layer over a bottom surface of the source/drain recess;
after the forming of the bottom dielectric layer, depositing a first epitaxial layer over the source/drain recess;
depositing a second epitaxial layer over the first epitaxial layer;
depositing a buffer layer over the second epitaxial layer;
depositing a third epitaxial layer over the buffer layer;
depositing a dielectric layer over the third epitaxial layer;
removing the dummy gate stack;
selectively removing the plurality of second semiconductor layers to release the plurality of first semiconductor layers as channel members; and
forming a gate structure to wrap around each of the channel members,
wherein the gate structure comprises a gate dielectric layer and a gate electrode over the gate dielectric layer,
wherein the gate electrode comprises a titanium-based material.

18. The method of claim 17, wherein the depositing of the buffer layer comprises use of dichlorosilane (DCS).

19. The method of claim 17, further comprising:
before the depositing of the buffer layer, treating the second epitaxial layer with an arsenic-containing gas.

20. The method of claim 19, wherein the arsenic-containing gas comprises arsenic hydride.
